(19) United States
(12) Patent Application Publication
(10) Pub. No.: US 2007/0032083 A1
(43) Pub. Date: Feb. 8, 2007

(54) Planarization method for manufacturing semiconductor device

(75) Inventor: Yong Soo Choi, Seongnam-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor, Inc., Icheon-si (KR)

(21) Appl. No.: 11/499,537

(22) Filed: Aug. 4, 2006

(30) Foreign Application Priority Data
Aug. 5, 2005 (KR) 10-2005-71909
Jun. 29, 2006 (KR) 10-2006-59879

(51) Int. Cl. H01L 21/461; H01L 21/311; H01L 21/302

(52) U.S. Cl. 438/692; 438/691; 438/694

(57) ABSTRACT

A method for planarizing a layer of a semiconductor device includes heating the layer to exhibit flowability, and applying pressure through an optically flat surface layer onto the layer to planarize the layer. And the planarizing method further comprises etch-back or chemical-mechanical polishing on the planarized layer.

### BACKGROUND

The present invention relates to semiconductor devices, and more particularly to a planarization method and methods for forming an interlayer dielectric layer (ILD), an isolation layer, and contact plugs using the planarization method.

In fabrication of a semiconductor device, a planarization method using chemical mechanical polishing (CMP) is mainly used. In the above planarization method using CMP, a mechanical action and a chemical action are simultaneously carried out, so they interact with each other.

More specifically, a wafer is polished using a pad and slurry. A table provided with the pad is simply rotated. A head is simultaneously rotated and vibrated while pressure of a designated intensity is applied to the head. The wafer is mounted on the head via surface tension or vacuum. The surface of the wafer contacts the pad by the load of the head and the pressure applied to the head, while slurry flows into a fine gap between the contact surfaces of the wafer and the pad. Thus, the wafer is mechanically polished by particles contained in the slurry and surface protrusions of the pad, while designated components are chemically removed from the wafer by chemicals contained in the slurry.

FIG. 1 is a schematic view illustrating one example of planarization by chemical mechanical polishing (hereinafter, referring to as a “CMP”).

With reference to FIG. 1, patterns 111 and 112 having various shapes and densities are disposed on a lower layer 100 or a semiconductor substrate. The patterns 111 and 112 include dense patterns 111, which have a comparatively small width and are closely disposed, and isolated patterns 112, which have a comparatively large width and are independently disposed.

An interlayer dielectric layer (hereinafter, referred to as an “ILD”) 120 is formed on the lower layer 100, on which the dense patterns 111 and the isolated patterns 112 are disposed. The ILD 120 is made of various dielectric materials. Particularly, in the case that the ILD 120 is made of low-k Spin On Glass (hereinafter, referred to as a “SOG”) formed through spin coating, the ILD 120 has an uneven surface due to the topology of the lower layer 100 and the different deposition characteristics resulting from the varying densities of patterns 111 and 112. A stepped portion (d) is formed between a portion of the ILD 120 provided with the dense patterns 111 and another portion of the ILD 120 provided with the isolated patterns 112. In this case, the surface of the ILD 120 is planarized so as to perform a subsequent process. Here, a planarization method by CMP may be used.

FIG. 2 is a schematic view illustrating problems caused by an ILD formed using a conventional planarization method by CMP. Here, elements in FIG. 2, which are the same as or similar to those in FIG. 1, are denoted by the same reference numerals even though they are depicted in different drawings.

With reference to FIG. 2, when the planarization of the SOG ILD 120 by CMP is performed, pressure, which is applied to the SOG ILD 120, generates cracks 150 in the SOG ILD 120 due to poor abrasion resistance, erosion resistance, and mechanical strength of the SOG, and causes various defects. Further, the SOG ILD 120 is damaged by chemicals during a subsequent cleaning process. Accordingly, the planarization of the SOG ILD 120 by CMP is performed after a double ILD structure, which includes the SOG ILD 120 and an oxide layer 130 formed on the SOG ILD 120, is created.

However, in this case, cracks 150 may be also generated in the SOG ILD 120 due to the thickness of the SOG ILD 120. Further, since the SOG ILD 120 has a large deposition thickness at the edge of the wafer, even though the SOG ILD 120 is planarized up to a target height, expressed by a dotted line 140, portions (A) of the SOG ILD 120 at the edges of the wafer are exposed to the outside. Accordingly, the SOG ILD 120 is still damaged by chemicals during a subsequent cleaning process.

The planarization by CMP is used to form an isolation layer, such as shallow trench isolation (hereinafter, referring to as a “STI”) layer, for isolating devices. When a silicon oxide layer, serving as a dielectric layer for the isolation layer, is deposited, the topology of the lower layer influences the topology of the deposited silicon oxide layer, and the topology of the deposited oxide layer reduces a depth of focus (DOF) margin during a subsequent gate exposure process. In order to solve this problem, planarization by CMP is used.

FIG. 3 is a schematic view illustrating a method for forming an isolation layer using the conventional planarization method by CMP.

With reference to FIG. 3, in order to form a STI layer, trenches 161 and 163 are formed in a semiconductor substrate 160 including a pad layer 170, which is a silicon nitride layer, while an isolation layer 180, which is a dielectric layer, fills the trenches 161 and 163. Thereafter, the isolation layer 180 is planarized by CMP, and is separated into isolation patterns, each of which fills the corresponding one of the trenches 161 and 163.

When the isolation layer 180 is deposited, a stepped portion is formed between a cell region provided with the first trenches 161, which have a comparatively high density and a comparatively small width, to a peripheral region provided with the second trenches 163, which have a comparatively low density and a comparatively large width, due to a difference of densities between the patterns. Further, when the isolation layer 180 is polished by CMP using the pad layer 170 as a polishing end point, a difference of polishing speeds between the cell region and the peripheral region occurs. Thereby, after the polishing is terminated, the remaining isolation layer 180 has a difference of thicknesses.

In the case that the polishing is performed using the cell region as a polishing target, various problems occur, such as a portion of the isolation layer 180, to be removed, remaining at the peripheral region, rounding (181) and dishing (183) of a corner of the pad layer 170 at a boundary between the cell region and the peripheral region, and thinning (185) of the remaining pad layer 170, occur. Thereby, it is possible to cause undesired attacks against the semiconductor substrate 160 made of silicon. In the case that a portion of the isolation layer 180, to be removed, remains, since the pad layer 170 is not exposed, a subsequent process for removing the pad layer 170 cannot be effectively performed.

In order to solve the above polishing problems, a method is proposed. In this method, a dummy active region is formed by adding dummy patterns of the pad layer 170 to the region provided with the second trenches 163 having a comparatively large width, or a stepped portion of the isolation layer is first reduced by etching back a portion of the isolation layer located on the dummy active region using a reverse mask, which has a reverse layout of the mask for forming trenches, and the isolation layer is then planarized by CMP. However, the above method requires additional steps, thus complicating a process for forming the isolation layer and increasing costs to perform the process.

Further, another method has been proposed. In this method, fumed silica based slurry, which is generally used in CMP, is replaced with ceria based slurry having a high selectivity, so as to achieve a high selectivity between the pad layer 170, which is a silicon nitride layer, and the isolation layer 180, which is a silicon oxide layer, thus preventing the polishing problems. However, the above method requires expensive ceria based slurry and a new supply device for the ceria based slurry. Further, the ceria based slurry generates scratches on the isolation layer 180.

Accordingly, development of an improved planarization process, which can be applied to the formation of a STI layer, is required.

### SUMMARY OF THE INVENTION

The present inventions provide planarization methods for fabricating a semiconductor device, which prevents stepped portions of a layer to be polished due to the topology of a layer located under the layer and defects in planarization of the layer caused thereby.

In accordance with one aspect of the present invention, there is provided a method for planarizing a layer of a semiconductor device comprising heating the layer to exhibit flowability, andapplying pressure to the layer to be planarized.

The layer is made of one selected from the group consisting of a photo-cured material, a thermosetting material, and thermoplastic material.

The layer is made of a material that exhibits flowability at more than a given temperature, the given temperature being no more than 300° C.

The heating of the target layer is performed by a furnace heating or an optical radiation.

The method further comprises performing etch-back or chemical-mechanical polishing on the planarized layer.

In accordance with another aspect of the present invention, there is a method for planarizing a layer of a semiconductor device comprising disposing an optically flat surface layer on the layer, heating the layer to exhibit flowability, applying pressure through the optically flat surface layer on the layer to be planarized, and removing the optically flat surface layer.

The optically flat surface layer is made of a transparent material that allows the layer to be heated by an optical radiation method.

The layer is made of a material that exhibits flowability at more than a given temperature, the given temperature being no more than 300° C.

The pressure applied to the layer is no more than 5 psi.

The method further comprises cleaning the layer after removing the optically flat surface layer.

The method further comprises performing etch-back or chemical-mechanical polishing on the planarized layer.

In accordance with another aspect of the present invention, there is an interlayer dielectric layer comprising forming a metal layer patterns over a semiconductor layer, depositing the interlayer dielectric layer to cover the metal layer patterns, heating the interlayer dielectric layer to exhibit flowability, and applying pressure to the interlayer dielectric layer to be planarized.

The interlayer dielectric layer is made of spin on glass (SOG), which exhibits flowability at a temperature not exceeding 300° C.

In accordance with another aspect of the present invention, there is a method for forming an interlayer dielectric layer comprising forming a metal layer patterns over a semiconductor substrate, depositing the interlayer dielectric layer to cover the metal layer patterns, disposing an optically flat surface layer on the interlayer dielectric layer, heating the interlayer dielectric layer to exhibit flowability, and applying pressure through the optically flat surface layer onto the interlayer dielectric layer to be planarized, and removing the optically flat surface layer.

The heating and applying pressure are performed simultaneously.

The interlayer dielectric layer is made of spin on glass (SOG), which exhibits flowability at more than a temperature, which does not exceed 300° C.

In accordance with another aspect of the present invention, there is a method for forming an isolation layer comprising forming trenches in a semiconductor substrate, forming a dielectric layer filling the trenches, forming a sacrificial layer over the dielectric layer, heating the sacrificial layer to exhibit flowability, applying pressure to the sacrificial layer to be planarized, and sequentially removing the planarized sacrificial layer and the dielectric layer to form separated patterns of the isolation layer from the dielectric layer.

The sacrificial layer is formed by applying one, selected from the group consisting of a photo-cured material, a thermosetting material, and thermoplastic material, to the dielectric layer.

The sacrificial layer is formed by applying a dielectric material, having the same removal rate as that of the dielectric layer.

The sacrificial layer is formed of spin on glass (SOG).

The removing the planarized sacrificial layer and the dielectric layer comprises etch-back or chemical-mechanical polishing on the sacrificial layer and the dielectric layer.

In accordance with another aspect of the present invention, there is a method for forming an isolation layer comprising forming trenches in a semiconductor substrate, forming a dielectric layer filling the trenches, forming a sacrificial layer over the dielectric layer, heating the sacrificial layer to exhibit flowability, disposing an optically flat surface layer on the sacrificial layer, applying pressure through the optically flat surface layer onto the sacrificial layer to be planarized, removing the optically flat surface layer, and removing the planarized sacrificial layer and the dielectric layer.

The removing the planarized sacrificial layer and the dielectric layer comprises etch-back or chemical-mechanical polishing on the sacrificial layer and the dielectric layer.

In accordance with another aspect of the present invention, there is a method for forming an isolation layer comprising, forming trenches in a semiconductor substrate,

forming a dielectric layer filling the trenches, heating the dielectric layer to exhibit flowability, applying pressure to the dielectric layer to be planarized, and removing the planarized dielectric layer.

The applying pressure to the dielectric layer comprises disposing an optically flat surface layer on the dielectric layer, applying pressure through the optically flat surface layer onto the dielectric layer, and removing the optically flat surface layer.

In accordance with another aspect of the present invention, there is a method for forming contact plugs comprising, forming an interlayer dielectric layer on a semiconductor substrate, forming contact holes formed through the interlayer dielectric layer, forming a conductive layer filling the contact holes, forming a sacrificial layer on the conductive layer, heating the sacrificial layer to exhibit flowability, applying pressure to the sacrificial layer to be planarized, and removing the planarized sacrificial layer and the conductive layer.

In accordance with yet another aspect of the present invention, there is a method for forming contact plugs comprising, forming an interlayer dielectric layer on a semiconductor substrate, forming contact holes formed through the interlayer dielectric layer, forming a conductive layer filling the contact holes, forming a sacrificial layer on the conductive layer, placing an optically flat surface layer, heating the sacrificial layer to exhibit flowability, applying pressure through the optically flat surface layer onto the sacrificial layer to be planarized, removing the optically flat surface layer, and removing the planarized sacrificial layer and the conductive layer.

The present invention provides a planarization method for manufacturing a semiconductor device, which prevents stepped portions of a target layer, to be planarized, due to the topology of a layer under the target layer, and defects in planarizing the target layer caused thereby.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a schematic view illustrating one example of planarization by chemical mechanical polishing (CMP);

FIG. 2 is a schematic view illustrating problems caused by an interlayer dielectric layer formed using a conventional planarization method by CMP;

FIG. 3 is a schematic view illustrating a method for forming an isolation layer using the conventional planarization method by CMP;

FIGS. 4 to 7 are sectional views illustrating a planarization method for fabricating a semiconductor device in accordance with one embodiment of the present invention;

FIGS. 8 to 10 are sectional views illustrating a planarization method for fabricating a semiconductor device in accordance with another embodiment of the present invention;

FIGS. 11 to 14 are sectional views illustrating a method for forming an interlayer dielectric layer of a semiconductor device in accordance with one embodiment of the present invention;

FIGS. 15 to 17 are sectional views illustrating a method for forming an interlayer dielectric layer of a semiconductor device in accordance with another embodiment of the present invention;

FIGS. 18 to 24 are sectional views illustrating a method for forming an isolation layer of a semiconductor device in accordance with one embodiment of the present invention;

FIGS. 25 to 28 are graphs illustrating effects of a method for forming an isolation layer of a semiconductor device in accordance with one embodiment of the present invention; and

FIGS. 29 and 30 are sectional views illustrating a method for forming contact plugs of a semiconductor device in accordance with one embodiment of the present invention.

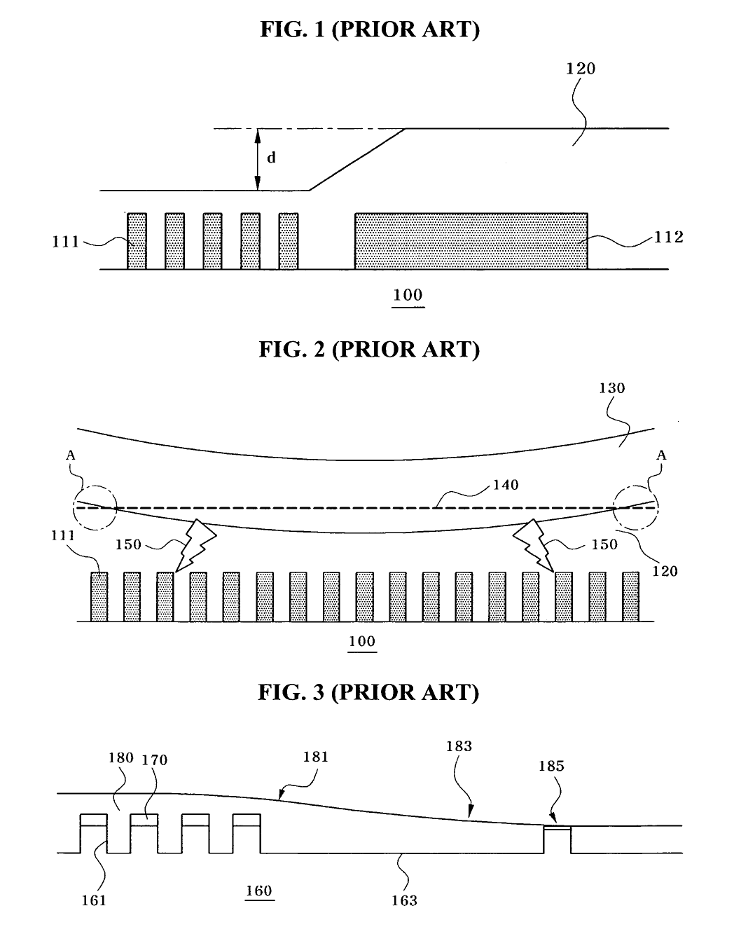

### DESCRIPTION OF THE PREFERRED EMBODIMENTS

Now, preferred embodiments of the present invention will be described in detail with reference to the annexed drawings.

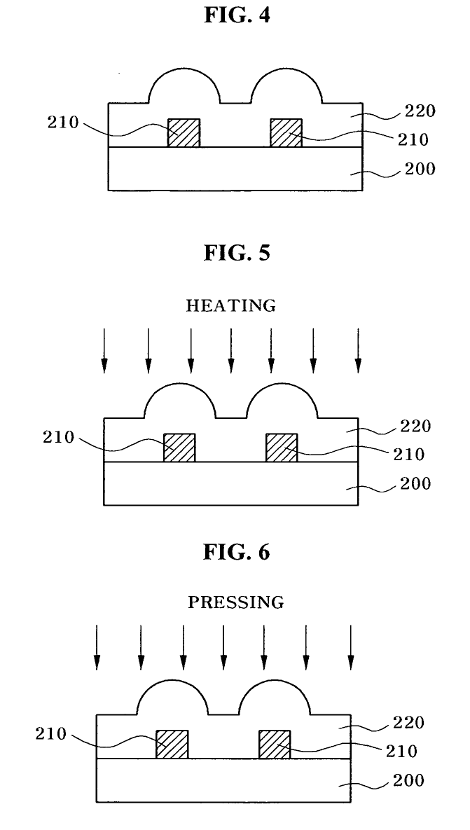

FIGS. 4 to 7 are sectional views illustrating a planarization method for fabricating a semiconductor device in accordance with one embodiment of the present invention.

With reference to FIG. 4, patterns 210 are disposed on a lower layer 200, and a target layer 220 is disposed on the lower layer including the patterns 210. Here, the lower layer 200 may be an ILD or a semiconductor substrate. The target layer 220 is a layer to be planarized, and preferably an ILD layer.

The target layer 220 to be planarized is made of a material having flowability at more than a designated temperature, which does not exceed 300° C. For example, the target layer 220 is made of a photo-cured material, a thermosetting material, or thermoplastic material. That is, the target layer 220 is made of a material, which exhibits flowability by applying heat or light thereto, or a material, which is cured from a flowable state by applying heat or light thereto.

The photo-cured material, which exhibits flowability prior to curing and is cured by applying light having more than a designated energy thereto, includes photoresist and epoxy. The thermosetting material, which has flowability and is cured by applying heat having more than a designated temperature thereto, includes benzocyclobutene (BCB), SOG, and an antireflection layer (ARC). The thermoplastic material, which exhibits flowability by applying heat thereto, includes polymethylmethacrylate (PMMA).

When the target layer 220 is coated on the lower layer 200 including the patterns 210 so that holes between the patterns 210 are filled with the target layer 220, the target layer 220 exhibits topology due to the patterns 210. Accordingly, a planarization process for reducing an exposure process margin or a DOF margin is required.

With reference to FIG. 4, the target layer 220 to be planarized is heated. Here, the target layer 220 is heated to more than a temperature, at which the target layer 220 exhibits flowability. As described above, the target layer 220 is made of a material exhibiting flowability at more than a temperature, which does not exceed 300° C. Accordingly, when the target layer 220 is heated to more than the above temperature, the target layer 220 exhibits flowability. As circumstances require, the heating temperature of the target layer 220 may exceed 300° C. In this case, other devices, which are not influenced by a temperature exceeding 300° C., must be disposed in the lower layer 200.

The target layer 220 can be heated by an optical radiation method, in which heat is transferred to the target layer 220 by radiating light, or a furnace heating method, in which heat is transferred to the target layer 220 in a furnace.

With reference to FIG. 6, pressure is applied to the target layer 220, which has flowability by heating. Since the target layer 220 exhibits flowability, and thus flows by pressure having a designated intensity. Thereby, the upper surface of the target layer 220 becomes even. When the pressure is applied to the target layer 220 for a designated time, the upper surface of the target layer 220 can be planarized, as shown in FIG. 7.

The target layer 220 may be an ILD or other dielectric layers. Further, the target layer 220 may be a layer for preventing dishing, rounding, thinning, or erosion of another layer located under the target layer 220 during planarization of the latter by CMP. That is, the target layer 220 is a buffer layer for alleviating a stepped portion of the lower layer, thus improving the uniformity in polishing the lower layer during the planarization of the lower layer by CMP.

FIGS. 8 to 10 are sectional views illustrating a planarization method for fabricating a semiconductor device in accordance with another embodiment of the present invention. Here, elements in FIGS. 8 to 10, which are the same as or similar to those in FIGS. 4 to 7, are denoted by the same reference numerals even though they are depicted in different drawings.

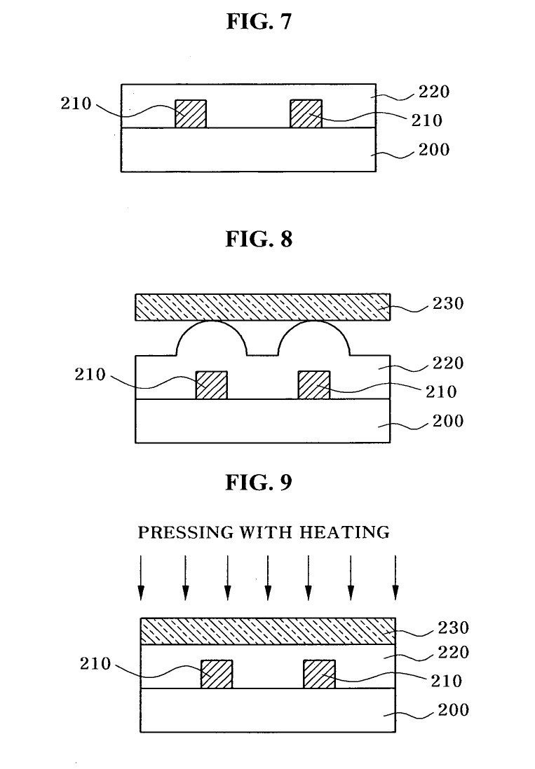

With reference to FIG. 8, an optically flat surface layer 230 is disposed on a target layer 220. Thereafter, as shown in FIG. 9, the optically flat surface layer 230 heats the target layer 220 and applies pressure to the target layer 220, thereby planarizing the upper surface of the target layer 220. The target layer 220 exhibits flowability by the above heating, and is planarized by the above application of the pressure.

Accordingly, the optically flat surface layer 230 serves to planarize the surface of the target layer 220. The optically flat surface layer 230 may be a flat pressing surface, which applies pressure, and may be a kind of mold having a pressing surface. Although not shown in the drawings, a press shaft for applying pressure, a driving motor serving as a unit for generating the pressure, and a hydraulic device are connected to the optically flat surface layer 230. Further, although not shown in the drawings, the optically flat surface layer 230 is provided with a heating unit, such as a heater or a heating light source.

Thereafter, as shown in FIG. 9, when the optically flat surface layer 230 is removed from the target layer 220, the target layer 220 having the planarized upper surface is obtained.

In this embodiment, the target layer 220 is also made of a photo-cured material, a thermosetting material, or thermoplastic material, and particularly made of a material exhibiting flowability at more than a designated temperature, which does not exceed 300° C., for example, SOG. The target layer 220 is heated by an optical radiation method. In this case, in order to allow the optically flat surface layer 220 to effectively transfer heat to the target layer 220, the optically flat surface layer 220 is made of a material transmitting light. The optically flat surface layer 230 applies pressure of approximately 5 psi or less to the target layer 220. Thereafter, although not shown in the drawings, a cleaning process is performed, thus removing contaminants, obtained by the contact with the optically flat surface layer 230, from the target layer 220.

FIGS. 11 to 14 are sectional views illustrating a method for forming an interlayer dielectric layer of a semiconductor device in accordance with one embodiment of the present invention.

First, with reference to FIG. 11, metal wiring layer patterns 310 are formed on a lower dielectric layer 300. Thereafter, an ILD 320 is formed on the lower dielectric layer 300 including the metal wiring layer patterns 310 by the same method as that of the above-described target layer 220. For example, the ILD 320 is made of SOG, which exhibits flowability at more than a designated temperature, which does not exceed 300° C. As circumstances require, instead of the metal wiring layer patterns, other patterns may be disposed on the lower dielectric layer 300.

Thereafter, with reference to FIG. 12, the ILD 320 is heated to more than a designated temperature. The heating temperature is a temperature, at which the ILD 320 exhibits flowability. The heating of the ILD 320 is performed by an optical radiation method or a furnace heating method.

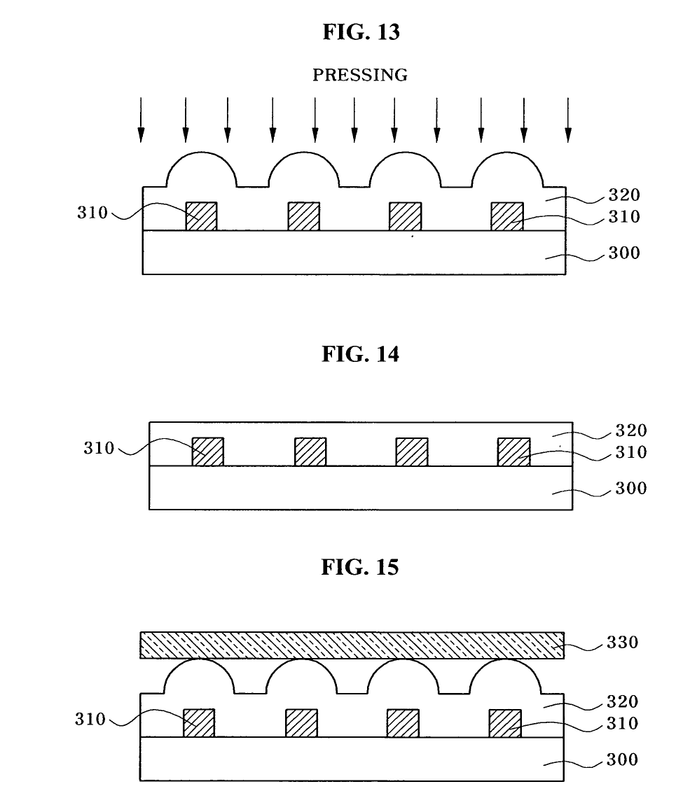

Thereafter, with reference to FIG. 13, pressure is applied to the ILD 320, which has flowability by heating. Since the ILD 320 exhibits flowability, the upper surface of the ILD 320 becomes even by pressure having a designated intensity. By applying the pressure to the ILD 320 for a designated time, the upper surface of the ILD 320 is planarized, as shown in FIG. 14.

FIGS. 15 to 17 are sectional views illustrating a method for forming an interlayer dielectric layer of a semiconductor device in accordance with another embodiment of the present invention. Here, elements in FIGS. 15 to 17, which are the same as or similar to those in FIGS. 11 to 14, are denoted by the same reference numerals even though they are depicted in different drawings.

First, as shown in FIG. 15, an optically flat surface layer 330 is disposed on an ILD 320. In this embodiment, the ILD 320 is also made of SOG, which exhibits flowability at more than a designated temperature, which does not exceed 300° C.

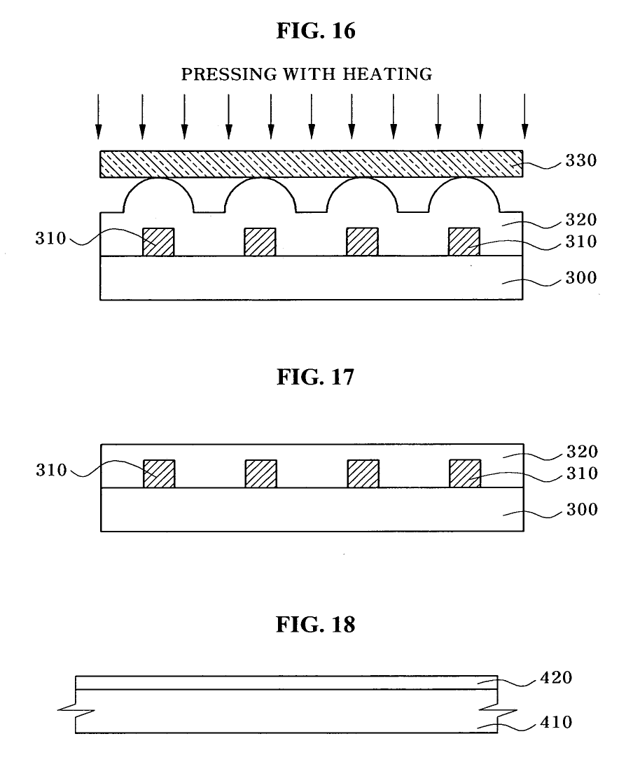

Thereafter, as shown in FIG. 16, the optically flat surface layer 330 heats the ILD 320 and applies pressure to the ILD 320, thereby planarizing the upper surface of the ILD 320. The ILD 320 exhibits flowability by the above heating, and is planarized by the above application of the pressure.

Thereafter, as shown in FIG. 17, when the optically flat surface layer 330 is removed from the ILD 320, the ILD 320 having the planarized upper surface is obtained. Thereafter, a process for forming patterns of the planarized ILD 320 according to purpose may be performed.

FIGS. 18 to 24 are sectional views illustrating a method for forming an isolation layer of a semiconductor device in accordance with one embodiment of the present invention.

In case that an optically flat surface layer applies pressure to the surface of a deposited material, which exhibits flowability at more than a designated temperature, for example, SOG, under the condition that the material is heated to the designated temperature, the material is globally planarized. The above method proposes a technique, for improving the uniformity of the thickness of the remainder of a dielectric layer after an isolation layer is planarized and separated into patterns corresponding to trenches by CMP, using the above fact.

That is, a stepped portion of the surface of the dielectric layer is firstly reduced, and then the surface of the dielectric layer is planarized by dry etching, such as etching back, or by CMP. Thereby, it is possible to prevent defects in removing strips of the silicon nitride pads due to the non-uniformity of the thickness of the remainder of the dielectric layer at some regions according to shapes or densities of the trenches under the dielectric layer after the planarization of the dielectric layer is completed. Further, it is possible to prevent attacks against the semiconductor substrate due to erosion, dishing, or thinning of the dielectric layer.

With reference to FIG. 18, a pad layer 420 is formed on a semiconductor substrate 410 according to an STI process. The pad layer 420 may include a silicon nitride layer. A silicon oxide layer, serving as a buffer layer, may be additionally formed under the silicon nitride layer.

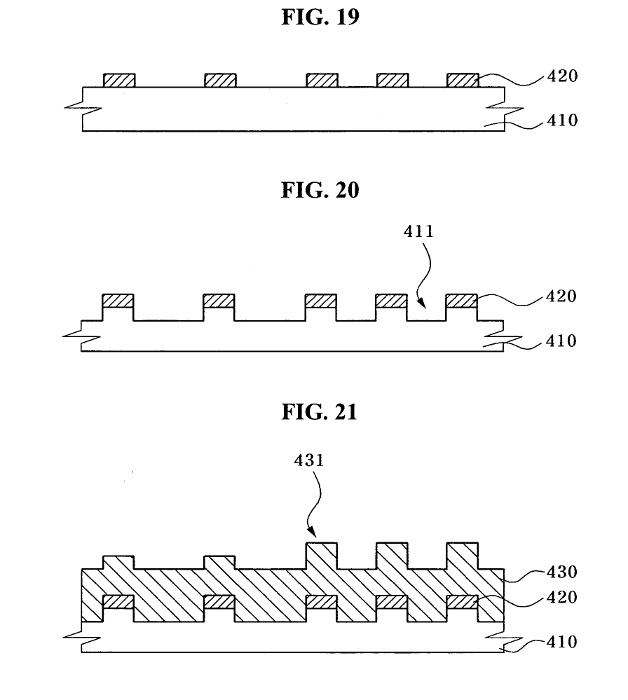

With reference to FIG. 19, the pad layer 420 is patterned, thus forming patterns exposing portions of the semiconductor substrate 410 for forming trenches, i.e., portions of the semiconductor substrate 410, at which an isolation layer is located.

With reference to FIG. 20, the exposed portions of the semiconductor substrate 410 are etched, thus forming trenches 411.

With reference to FIG. 21, a dielectric layer 430 filling the trenches 411 is formed on the semiconductor substrate 410. The dielectric layer 430 may include a silicon oxide layer. The dielectric layer 430 may have stepped portions 431 according to the shapes and densities of the trenches 411 under the dielectric layer 430.

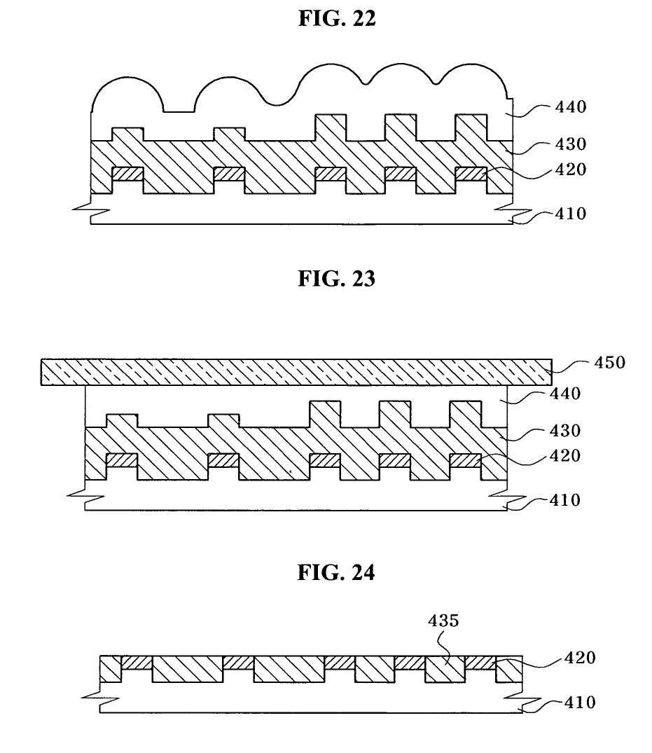

With reference to FIG. 22, a target layer 440 or sacrificial layer, to be planarized for reducing the stepped portions 431 of the dielectric layer 430, is formed on the dielectric layer 430. The target layer 440 to be planarized is the same as the target layer 220 (in FIG. 4) and the ILD 320 (in FIG. 11).

The target layer 440 is obtained by applying a photo-cured material, a thermosetting material, or thermoplastic material to the dielectric layer 430. Preferably, the target layer 440 is obtained by applying a dielectric material, which has the same removal speed as that of the dielectric layer 430 during a removal process (i.e., etching back or CMP) for separating the isolation layer, for example, SOG, on the dielectric layer 430.

With reference to FIG. 23, the target layer 440 is heated to a temperature, at which the target layer 440 exhibits flowability, and pressure is then applied to the target layer 440 having flowability. Thereby, the target layer 440 is firstly planarized. This process is the same as the processes described with reference to FIGS. 5 and 6, FIGS. 8 and 9, and FIG. 16.

For example, an optically flat surface layer 450 is disposed on the target layer 440, and pressure of at most 5 psi is applied to the optically flat surface layer 450 contacting the target layer 440. Thereby, the target layer 440 having flowability is planarized. Then, the optically flat surface layer 450 is removed from the surface of the target layer 440.

The heating of the target layer 440 is performed by an optical radiation method, or a furnace heating method.

After the target layer 440 is firstly planarized, the planarized target layer 440 and the dielectric layer 430 are sequentially removed from the surface of the semiconductor substrate 410. Thereby, as shown in FIG. 24, an isolation layer 435 having patterns corresponding to the trenches 411 are formed. The pad layer 420 is used as a polishing end point for the CMP.

As described above, after the initial stepped portions 431 of the dielectric layer 430 are alleviated by the target layer 440, the target layer 440 and the dielectric layer 430 are polished using the CMP until the pad layer 420 under the dielectric layer 430 is exposed. Here, since the dielectric layer 430 and the target layer 440 have the same polishing speed, they are considered to be as the same layer during the second planarization process. Thereby, it is possible to improve the uniformity of the thickness of the remaining layer.

Accordingly, although the CMP does not use ceria based slurry having a high selectivity but uses fume silica based slurry, it is possible to further improve the uniformity of the thickness of the remaining layer and the uniformity of polishing the layers. Thereby, it is possible to reduce costs to perform the STI CMP and to effectively reduce scratches caused due to the ceria based slurry.

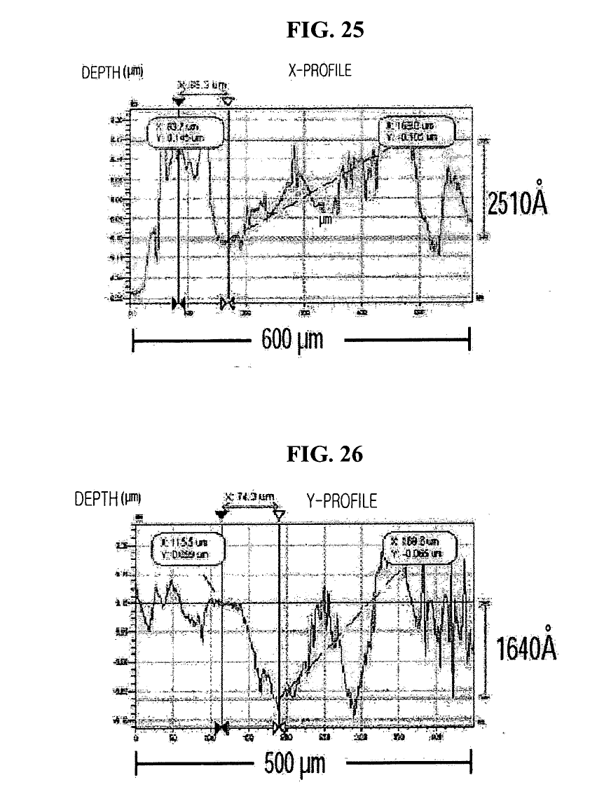

FIGS. 25 to 28 are graphs illustrating effects of a method for forming an isolation layer of a semiconductor device in accordance with one embodiment of the present invention. FIGS. 25 and 26 are graphs respectively illustrating remaining stepped portions of a dielectric layer along an X-profile and a Y-profile, after the dielectric layer filling trenches for isolating devices are deposited on a region of a semiconductor device, which is planarized by CMP. As shown in FIGS. 25 and 26, in the conventional method, stepped portions had a depth difference of approximately 2,510 Å in the X-profile and a depth difference of approximately 1,640 Å in the Y-profile.

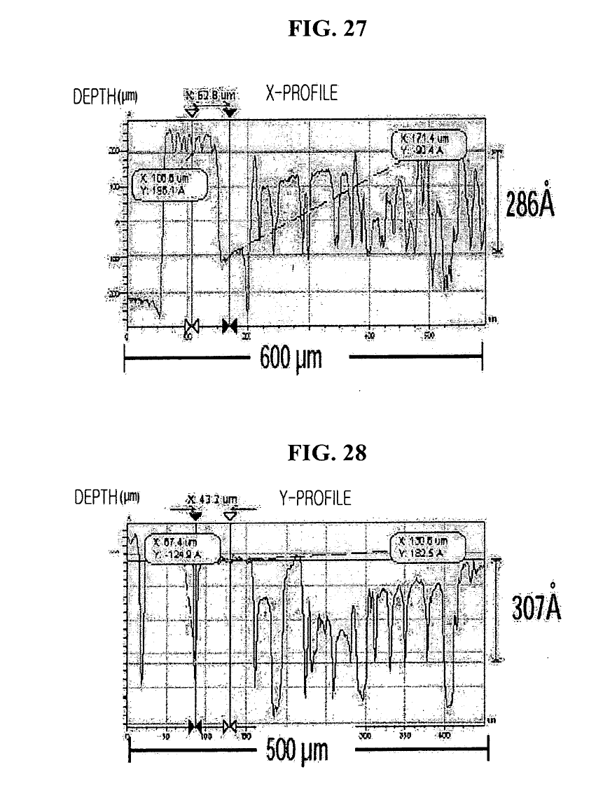

On the other hand, FIGS. 27 and 28 are graphs respectively illustrating remaining stepped portions of a dielectric layer along an X-profile and a Y-profile, after the dielectric layer filling trenches for isolating devices is deposited on the region of the semiconductor device, which is firstly planarized using a target layer, and is secondly planarized by CMP.

As shown in FIGS. 27 and 28, in the method of one embodiment of the present invention, stepped portions had a depth difference of approximately 286 Å in the X-profile and a depth difference of approximately 307 Å in the Y-profile. Accordingly, the method of one embodiment of the present invention achieves the reduction of the stepped portions of the dielectric layer, compared to the conventional method, as shown in FIGS. 25 and 26.

FIGS. 18 to 24 illustrates a method for forming an isolation layer of a semiconductor device in accordance with one embodiment of the present invention, in which the dielectric layer 430 filling the trenches 411 is formed on the semiconductor substrate 410 and the target layer 440 is formed on the dielectric layer 430. However, the above method may be modified.

For example, the trenches 411 are filled with a dielectric layer made of a dielectric material having flowability at more than a designated temperature, such as SOG. The SOG dielectric layer is heated to the above temperature, and pressure is applied to the dielectric layer having flowability. Thereby, the dielectric layer is firstly planarized. Then, the firstly-planarized dielectric layer is secondarily planarized by the CMP, thus forming an isolation layer having separated patterns corresponding to the trenches. Here, the dielectric layer may be made a photo-cured material, a thermosetting material, or thermoplastic material.

The above-described embodiments of the present invention may be applied to other semiconductor device fabrication processes using a planarization method, such as CMP. For example, the embodiments of the present invention are applied to a process for forming contact plugs, in which a conductive layer is deposited and is planarized by CMP so as to achieve node separation of the conductive layer.

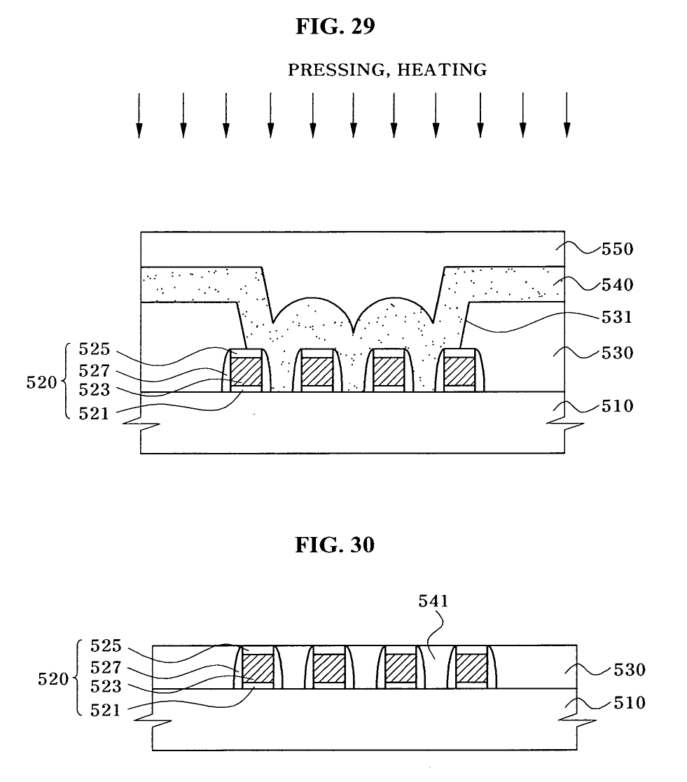

FIGS. 29 and 30 are sectional views illustrating a method for forming contact plugs of a semiconductor device in accordance with one embodiment of the present invention.

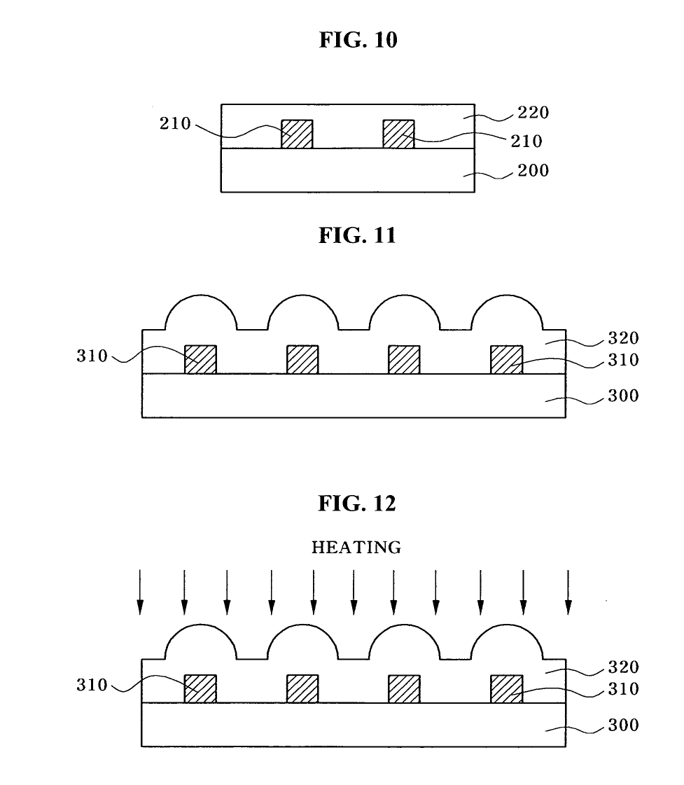

With reference to FIG. 29, an ILD 530 is formed on a semiconductor substrate 510 including structures, such as gate stacks 520. The ILD 530 may be formed by the same method as that of the ILD 320 (FIG. 17) with reference to FIGS. 10 to 17. Each of the gate stacks 520 includes a gate oxide layer 521, a gate conductive layer 523, a hard mask 525, and a spacer 527.

Thereafter, in order to electrically connect the semiconductor substrate 510 and other capacitors or bit lines formed thereon, contact holes 531 are formed through the ILD 530. Here, a plurality of contact holes may be respectively formed between the gate stacks 520, or a line-type or band-type contact hole may be formed so that the contact hole can be separated into a plurality of sub contact holes by the gate stacks 520.

Thereafter, a conductive layer 540 filling the contact holes 531, for example, a conductive polysilicon layer, is deposited on the semiconductor substrate 510. The conductive layer 540 has a topology provided with stepped portions based on the topologies of the contact holes 531 or the topologies of other patterns.

A target layer 550 to be planarized is formed on the conductive layer 540. The target layer 550 serves to reduce the stepped portions of the conductive layer 540. The target layer 550 may be formed by the same method described with reference to FIG. 22. Thereafter, the target layer 550 is heated to a temperature, at which the target layer 550 exhibits flowability, and pressure is applied to the target layer 550 having flowability. Thereby, the target layer 550 is planarized. This process may be the same as the process described with reference to FIG. 23.

Thereafter, as shown in FIG. 20, the planarized target layer 550 and the conductive layer 540 are sequentially removed from the surface of the semiconductor substrate 510, preferably by CMP. The CMP is performed using the hard mask 525 preferably including a silicon nitride layer as a polishing end point. Thereby, contact plugs 541, which are separated from each other corresponding to the contact holes 531 located between the gate stacks 520, are formed.

The use of the target layer 550 to be planarized reduces the stepped portions of the conductive layer 540, and thus improves the polishing uniformity in the CMP for achieving the node separation of the contact plugs 541. Thereby, it is possible to prevent bridge of the contact plugs 541 or damage to the hard mask 521 due to excessive polishing.

Further, the target layer of the present invention may be used in other semiconductor device fabrication processes using the planarization method, such as CMP, so as to improve the polishing uniformity.

As apparent from the above description, the present invention provides a planarization method for fabricating a semiconductor device and a method for forming an interlayer dielectric layer using the same. Compared to the conventional planarization method using CMP, the methods of the present invention reduce the amount of chemicals consumed and the amount of by-products generated, thus reducing defects generated due to the by-products. The methods of the present invention do not require dummy patterns, which are required by the conventional planarization method using CMP, thus preventing deterioration of performance characteristics of the device due to parasitic capacitance by the dummy patterns.

Further, the present invention provides a method for forming an isolation layer, which effectively reduces a difference of thicknesses of the remainder of a dielectric layer caused by initial stepped portions of the dielectric layer. Accordingly, the method of the present invention omits the use of ceria based slurry having a high selectivity. Thereby, it is possible to prevent scratches on the surface of the isolation layer due to the use of the ceria based slurry. Further, the method of the present invention omits the use of a reverse mask and an etching process for preventing a pad layer from being incompletely removed due to non-exposure. Thus, it is possible to simplify a process for forming the isolation layer and reduce production costs of the isolation layer.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method for planarizing a layer of a semiconductor device comprising:
heating the layer to exhibit flowability; and
applying pressure to the layer to be planarized.

2. The method according to claim 1, wherein the layer is made of one selected from the group consisting of a photo-cured material, a thermosetting material, and thermoplastic material.

3. The method according to claim 1, wherein the layer is made of a material that exhibits flowability at more than a given temperature, the given temperature being no more than 300° C.

4. The method according to claim 1, wherein the heating of the target layer is performed by a furnace heating or an optical radiation.

5. The method according to claim 1, further comprising
performing etch-back or chemical-mechanical polishing on the planarized layer.

6. A method for planarizing a layer of a semiconductor device comprising:
disposing an optically flat surface layer on the layer;
heating the layer to exhibit flowability;
applying pressure through the optically flat surface layer on the layer to be planarized; and
removing the optically flat surface layer.

7. The method according to claim 6, wherein the optically flat surface layer is made of transparent material that allows the layer to be heated by an optical radiation method.

8. The method according to claim 6, wherein the layer is made of one selected from the group consisting of a photo-cured material, a thermosetting material, and thermoplastic material.

9. The method according to claim 6, wherein the layer is made of a material that exhibits flowability at more than a given temperature, the given temperature being no more than 300° C.

10. The method according to claim 6, wherein the pressure applied to the layer is no more than 5 psi.

11. The method according to claim 6, further comprising cleaning the layer after removing the optically flat surface layer.

12. The method according to claim 6, further comprising
performing etch-back or chemical-mechanical polishing on the planarized layer.

13. A method for forming an interlayer dielectric layer comprising:
forming a metal layer patterns over a semiconductor layer;
depositing the interlayer dielectric layer to cover the metal layer patterns;
heating the interlayer dielectric layer to exhibit flowability; and
applying pressure to the interlayer dielectric layer to be planarized.

14. The method according to claim 13, wherein the interlayer dielectric layer is made of spin on glass (SOG), which exhibits flowability at a temperature not exceeding 300° C.

15. A method according to claim 13, further comprising performing etch-back or chemical-mechanical polishing on the planarized interlayer dielectric layer.

16. A method for forming an interlayer dielectric layer comprising:
forming a metal layer patterns over a semiconductor substrate;
depositing the interlayer dielectric layer to cover the metal layer patterns;
disposing an optically flat surface layer on the interlayer dielectric layer;
heating the interlayer dielectric layer to exhibit flowability; and
applying pressure through the optically flat surface layer onto the interlayer dielectric layer to be planarized; and
removing the optically flat surface layer.

17. the method according the claim 16, wherein the heating and applying pressure are performed simultaneously.

18. The method according to claim 16, wherein the interlayer dielectric layer is made of spin on glass (SOG), which exhibits flowability at more than a temperature, which does not exceed 300° C.

19. A method according to claim 16, further comprising etch-back or chemical-mechanical polishing on the planarized interlayer dielectric layer.

20. A method for forming an isolation layer comprising:
forming trenches in a semiconductor substrate;
forming a dielectric layer filling the trenches;
forming a sacrificial layer over the dielectric layer;
heating the sacrificial layer to exhibit flowability;
applying pressure to the sacrificial layer to be planarized; and
removing the planarized sacrificial layer and the dielectric layer.

21. The method according to claim 20, wherein the sacrificial layer is formed by applying one, selected from the group consisting of a photo-cured material, a thermosetting material, and thermoplastic material, to the dielectric layer.

22. The method according to claim 20, wherein the sacrificial layer is formed by dielectric material, having the same removal rate as that of the dielectric layer.

23. The method according to claim 22, wherein the dielectric material for the sacrificial layer is spin on glass (SOG).

24. The method according to claim 20, wherein the removing the planarized sacrificial layer and the dielectric layer comprises etch-back or chemical-mechanical polishing on the sacrificial layer and the dielectric layer.

25. A method for forming an isolation layer comprising:
forming trenches in a semiconductor substrate;
forming a dielectric layer filling the trenches;
forming a sacrificial layer over the dielectric layer;
heating the sacrificial layer to exhibit flowability;
disposing an optically flat surface layer on the sacrificial layer;
applying pressure through the optically flat surface layer onto the sacrificial layer to be planarized;
removing the optically flat surface layer; and
removing the planarized sacrificial layer and the dielectric layer.

26. The method according to claim 25, wherein the removing the planarized sacrificial layer and the dielectric layer comprises etch-back or chemical-mechanical polishing on the sacrificial layer and the dielectric layer.

27. A method for forming an isolation layer comprising:
forming trenches in a semiconductor substrate;
forming a dielectric layer filling the trenches;
heating the dielectric layer to exhibit flowability;
applying pressure to the dielectric layer to be planarized; and
removing the planarized dielectric layer.

28. The method according to claim 26, wherein the applying pressure to the dielectric layer comprises:
disposing an optically flat surface layer on the dielectric layer;
applying pressure through the optically flat surface layer onto the dielectric layer; and
removing the optically flat surface layer.

29. A method for forming contact plugs comprising:
forming an interlayer dielectric layer on a semiconductor substrate;
forming contact holes formed through the interlayer dielectric layer;
forming a conductive layer filling the contact holes;
forming a sacrificial layer on the conductive layer;
heating the sacrificial layer to exhibit flowability;
applying pressure to the sacrificial layer to be planarized; and
removing the planarized sacrificial layer and the conductive layer.

30. A method for forming contact plugs comprising:
forming an interlayer dielectric layer on a semiconductor substrate;
forming contact holes formed through the interlayer dielectric layer;
forming a conductive layer filling the contact holes;
forming a sacrificial layer on the conductive layer;
placing an optically flat surface layer
heating the sacrificial layer to exhibit flowability;
applying pressure through the optically flat surface layer onto the sacrificial layer to be planarized;
removing the optically flat surface layer; and
removing the planarized sacrificial layer and the conductive layer.
